(19) United States
(12) Patent Application Publication
(10) Pub. No.: US 2024/0085504 A1
(43) Pub. Date: Mar. 14, 2024

(54) PASSIVE REDUCTION OF TEMPERATURE-INDUCED SHIM DRIFT IN NMR MAGNET SYSTEMS

(71) Applicant: Bruker Switzerland AG, Fällanden (CH)

(72) Inventors: Markus MAYER, Gossau (CH); Beat GROSSNIKLAUS, Neerach (CH); Pierre-Alain BOVIER, Zürich (CH); Rafael CAMINADA, Winkel (CH)

(21) Appl. No.: 18/354,987

(22) Filed: Jul. 19, 2023

(30) Foreign Application Priority Data
Jul. 21, 2022 (DE) 10 2022 207 486

(51) Int. Cl. G01R 33/3815; H01F 6/04; H01F 6/06

(52) U.S. Cl. CPC G01R 33/3815; H01F 6/04; H01F 6/06

(57) ABSTRACT

An NMR apparatus having a magnet coil system for generating a homogeneous magnetic field comprises a superconducting magnet within a vacuum vessel in the cold region of a cryostat and a shim system containing shim elements outside the vacuum vessel, wherein the magnet has a first mechanical connection point to the vacuum vessel via a magnet suspension, and the shim system has a second mechanical connection point to the vacuum vessel via a positioning element. On at least one portion of a path along the vacuum vessel from the first mechanical connection point to the second mechanical connection point and/or on at least one portion of a path along the positioning element from the second mechanical connection point to the shim system, only materials whose thermal expansion coefficient at operating temperature is less than 5 ppm/K are used. Magnetic field homogeneity can thus be kept largely stable and constant.

The invention relates to an NMR apparatus having a magnet coil system for generating a homogeneous magnetic field, which comprises a superconducting magnet arranged within a vacuum vessel in the cold region of a cryostat, and which comprises a shim system containing shim elements arranged outside the vacuum vessel, wherein the superconducting magnet has a first mechanical connection point to the vacuum vessel via a magnet suspension, and wherein the shim system has a second mechanical connection point to the vacuum vessel via a positioning element.

Such an NMR apparatus is known from patent publication DE 101 04 365 C1.

### BACKGROUND OF THE INVENTION

The present invention relates very generally to the field of nuclear magnetic resonance (NMR), and in particular to cooled NMR magnet systems that are generally superconducting during operation and in which the homogeneity of the NMR magnetic field is further improved by a shim system.

NMR spectroscopy is a widely used and powerful method in instrumental analysis, with the aid of which the electronic environment of individual atoms and the interaction of the individual atoms with the adjacent atoms can be examined in a substance to be analyzed, such as a hydrocarbon or a bio-inorganic complex compound. In this way, for example, the composition, structure, and dynamics of the substance to be analyzed can be made clear, and the concentration of the substance to be analyzed can likewise be determined.

In an NMR measurement, the substance is exposed to a strong static, homogeneous magnetic field Bo, which aligns the nuclear spins in the substance. High-frequency electromagnetic pulses are then radiated into the substance to be analyzed. The high-frequency electromagnetic fields generated in this way are detected in the NMR spectrometer. Information about the properties of the examined substance can then be obtained from this.

Both in high-resolution magnetic resonance spectroscopy and in magnetic resonance imaging, the requirements for magnetic field homogeneity are very high. In order to achieve the homogeneity specifications, electrical cryoshims are frequently used. Their coils generate elementary field profiles. Provided with suitable currents, they can improve the homogeneity of the NMR magnet at the sample site.

Sometimes, cold ferromagnetic material (for example, iron alloys or steel alloys) is also used as a shim element for improving homogeneity, as described, for example, in patent publication DE 10 2015 225 731 B3. Regardless of how a magnet is cold-shimmed, residual inhomogeneity remains at the end and must be corrected in the magnet bore outside the vacuum vessel. So-called room-temperature shims (hereafter referred to as “RT shims”) are used for this purpose. Like the cryoshims, these room-temperature shims can comprise either coils, ferromagnetic material, or a combination of the two. Although the name, “room-temperature shims,” suggests that these shims are at the laboratory temperature, this is not necessarily the case; the power dissipated in the shim coils often causes their temperature to be slightly increased compared to the laboratory temperature. In addition, NMR experiments with sample substances are also sometimes carried out at variable temperatures. Hereafter, for the sake of simplicity, “RT shims” and “room temperature” are nevertheless always spoken of. The RT shims thus do not necessarily have to be operated at room temperature.

The superconducting NMR magnet is mechanically connected to the RT shims over a long path. A part of this path extends in the cold region of a cryostat, and another part is at room temperature. The latter part of the path follows the fluctuations of the ambient temperature and changes its length due to its thermal expansion; consequently, a relative movement between the superconducting magnet and the RT shims occurs. The RT shims are then no longer ideally matched for compensating for the field homogeneity, and the quality of the magnetic resonance images or magnetic resonance spectra deteriorates.

If the RT shims comprise coils or coil systems, their currents can be adjusted, and the original quality can thus be restored. A similar shift in the RT shim currents would be observed if these currents were drifting themselves—for example, due to temperature-dependent current sources. In the following, it is therefore sometimes said (rather casually) that the RT shim currents “drift” with the ambient temperature.

Although sensitive devices are often operated in air-conditioned rooms, temperature fluctuations of 1° C. during the day are nevertheless not uncommon. In many applications, the RT shim currents can be adjusted automatically. If this is not possible, the homogeneity fluctuations during the measurement can be disruptive.

Comparable homogeneity fluctuations occur when the temperature, e.g., in the magnet bore, varies over time for other reasons. Such a situation occurs, for example, when the NMR test sample is changed, and shimming must be performed again. The power dissipated by the RT shims may differ from the previous RT shim power and cause new temperature conditions in the magnet bore. It then takes a certain amount of time until the temperature evens out to the new level. During this time, the shim currents must be adjusted again and again. A similar problem occurs when the temperature of the NMR test sample is changed.

An obvious solution to the problem can in a first approximation consist in keeping the fluctuations of the ambient temperature as small as possible. The larger the laboratory, the more expensive and more complicated it is to operate an air conditioner with sufficient precision.

In a second, refined approach, the shim currents can be automatically adapted to the fluctuating homogeneity. However, this is possible only if a lock substance is available, which is not the case, for example, in solid-state experiments.

A high-resolution NMR spectrometer with a superconducting NMR magnet coil system, which is cooled to cryogenic temperatures with a pulse tube refrigerator and which is arranged within a vacuum vessel in the cold region of a cryostat, is described in patent publication EP 0 780 698 Bl.

Patent publication EP 2 015 092 A1 addresses the problem of shim drift due to atmospheric pressure fluctuations. Similarly as with temperature fluctuations, a relative movement between the RT shims and the superconducting magnet occurs. In order to minimize the relative movement, a bridge is used, which is fixed to the outer edge of the cryostat and thus does not follow the movement of the central region of the cryostat during pressure fluctuations. The RT shim system is fastened to this bridge.

Quantitative clinical NMR analysis instruments with automatic compensation for temperature sensitivity over a wide temperature range are described in patent publication EP 3 686 620 A1.

The publication, “Acyclic Acids—Advances in Research and Application: 2013 Edition: ScholarlyBrief,” Q. Ashton Acton, PhD, ScholarlyEditions, 2013, p. 139, likewise discusses the temperature sensitivity of the electronics in NMR analyzers. Temperature control of the electronics can accordingly provide a remedy.

The publication, “Modern Instrumental Analysis,” Satinder Ahuja, Neil Jespersen, Elsevier, 2006, p. 270, points to the temperature sensitivity of the sample substance. By means of temperature regulation at the location of the substance, this effect can be counteracted.

Patent publication DE 10 2015 225 731 B3 cited above discloses a helium-cooled, superconducting magnet coil system in an NMR apparatus with an easily accessible, likewise low-temperature-cooled NMR shim arrangement. The NMR apparatus has a field shaping device between a helium inner tube and a radiation shield inner tube, which device is in rigid mechanical contact with the helium vessel, without touching the radiation shield inner tube.

Patent publication DE 101 04 365 C1 (likewise cited above) discloses an NMR apparatus which, with respect to the present invention, is generic, with all feature complexes defined at the outset, including the shim system of the generic type. However, the problems described above about fluctuations in the magnetic field homogeneity due to usual laboratory temperature changes exist in this apparatus as well.

### SUMMARY OF THE INVENTION

The present invention involves modifying an NMR apparatus with the features defined at the outset with the aid of particularly simple, easily accessible technical means and as cost-effectively as possible, such that the magnetic field homogeneity is kept largely stable and constant within and in the surroundings of the apparatus even in changing temperature conditions.

In particular, on at least one portion of a path along the vacuum vessel from a first mechanical connection point between the magnet suspension and the vacuum vessel to a second mechanical connection point between the positioning element for the shim system and the vacuum vessel and/or on at least one portion of a path along the positioning element from the second mechanical connection point to the shim system, only materials whose thermal expansion coefficient at operating temperature is less than 5 ppm/K are used.

The present invention thus proposes achieving stable magnetic field homogeneity on the paths by means of the prescribed material selection.

As a result of the configuration of the paths, and in particular because of the low thermal expansion coefficient of the selected materials, the strain change of the corresponding path portion during a temperature fluctuation is minimized, so that the relative movement between the superconducting magnet and the shim system is kept small. As a result, field homogeneity remains stable.

Conventional metallic materials, such as steel or aluminum, have a thermal expansion coefficient of approximately 20 ppm/K at room temperature. In order to reduce the relative movements between the shim system and the superconducting magnet due to fluctuations of the room temperature, materials with a much smaller thermal expansion can be used on the connecting path of these two components.

Carbon fiber-reinforced plastic (CFRP) has a thermal expansion coefficient of less than 1 ppm/K along its fibers. This material can be used, for example, in the magnet bore in parts of the positioning element for the shim system.

In the case of the steel grade Invar, the thermal expansion coefficient is less than 2 ppm/K. This steel can be used in parts of the vacuum vessel. On the other hand, CFRP is unsuitable as a material for the vacuum vessel, since it cannot be welded.

Relative movements can also be reduced by using a control loop to keep the temperature constant on a portion of the connecting path between the superconducting magnet and the shim system. The temperature or the strain is measured at different locations, and heating takes place if necessary. The regions with heaters are artificially kept warmer than ambient temperature. Alternatively, it is also possible to cool with TEC elements (thermo-electric coolers). The regions with TEC elements are then artificially kept colder than ambient temperature.

The temperature in the bore of the magnet can also be kept constant with a temperature-controlled gas.

In very particularly preferred embodiments of the NMR apparatus according to the invention, it is provided that the length of the path portion along the vacuum vessel from the first mechanical connection point to the second mechanical connection point and/or the length of the path portion along the positioning element from the second mechanical connection point to the shim system be in each case more than 50% of the overall length of the corresponding path.

Shim coils are usually wound on an aluminum former. Due to its good thermal conductivity, aluminum has the advantage that the heat dissipated in the coils is transported away well. However, aluminum has a large thermal expansion coefficient of approximately 23 ppm/K. In the implementation of the invention, only the connecting piece from the aluminum former of the shim coils to the second mechanical connection point is manufactured from a material with a low thermal expansion coefficient. If the shim elements are not coils, but plates made of ferromagnetic material, even the entire positioning element can be manufactured from a material with a low thermal expansion coefficient. Outside the magnet bore, the spherical cap of the vacuum vessel and its connecting flange to the inner tube are also not necessarily manufactured from a material with a low thermal expansion coefficient. With this background, materials with a low thermal expansion coefficient can, however, easily be used on more than 50% of the overall length of the paths.

Particularly advantageous are also embodiments of the NMR apparatus according to the invention in which materials that have different thermal expansion coefficients whose thermal expansions mutually compensate for one another are used in portions on the path along the vacuum vessel from the first mechanical connection point to the second mechanical connection point and/or on the path along the positioning element from the second mechanical connection point to the shim system. Thus, only significantly lower absolute thermal expansions remain, which can finally be further minimized in the framework of a fine adjustment with the aid of the invention.

Likewise advantageous are embodiments in which Invar is used as the material on the at least one portion of the path along the vacuum vessel from the first mechanical connection point to the second mechanical connection point.

A reduction in the relative movements between the superconducting magnet and the shim system is advantageous in this case. Invar typically has a thermal expansion coefficient of less than 2 ppm/K. Invar also has the advantage that it can be welded. The vacuum vessel must be vacuum-tight, which is very demanding for all mechanical connections. The partial path mentioned here would extend over one or more suspension turrets in a common cryostat with a vertical magnet bore.

However, Invar gets magnetized by the background field of the superconducting magnet. Since Invar is only located in a small stray field region of the superconducting magnet, no disadvantages are to be expected, at least in the case of actively shielded magnets. The forces and the interference field of the magnetization are in any case small.

Alternatively or additionally, in further embodiments of the invention, CFRP (carbon fiber-reinforced plastic) is used as the material on the at least one portion of the path along the positioning element from the second mechanical connection point to the shim system. Typically, CFRP has a thermal expansion coefficient of less than 1 ppm/K along its fibers. As a result of the low thermal expansion coefficient, the strain change during a temperature fluctuation is minimized, so that the relative movement between the superconducting magnet and the shim system is kept small. As a result, field homogeneity remains stable.

In particular developments of these embodiments, the distance from the first mechanical connection point to the second mechanical connection point is less than 10 cm.

Advantageously, the thermal expansion of CFRP or similar materials is less than the thermal expansion of all metals, including Invar. It is therefore expedient to use such materials on the largest possible proportion of the connection length between the shim system and the first mechanical connection point. In practice, the positioning element for the shim system can be fixed to the suspension turrets with a scaffold made of CFRP.

Embodiments of the invention in which materials whose thermal conductivity at operating temperature is greater than 50 W/(mK)—in particular, copper—are used on at least one portion of a further path along the positioning element from the second mechanical connection point to the shim system are also advantageous.

If high currents are required in the shim elements, there is a risk of overheating. This problem can be counteracted by inserting, into the positioning element, material, e.g., sliding copper rails, that is thermally well-conductive but does not contribute mechanically, or contributes mechanically only slightly, to the thermal expansion of the positioning element. A sliding tube made of aluminum or copper can also be used in parallel to the positioning element. The use of flush gas also contributes to the dissipation of heat.

Further advantageous embodiments of the NMR apparatus according to the invention include shim elements that are designed as electrical coils and/or as ferromagnetic elements.

Ferromagnetic elements have the advantage that they contribute to field homogenization without dissipating heat. They are usually used in devices for magnetic resonance tomography. Electrical shim coils are characterized in that their current is variable, and that they can therefore react dynamically to homogeneity fluctuations. In high-resolution nuclear magnetic resonance, shim coils are indispensable. However, they can be combined with ferromagnetic elements.

In other embodiments of the invention, the vacuum vessel has a vertical room-temperature bore in which the shim system is arranged, and the positioning element comprises a clamping ring, wherein the contact surface of the clamping ring forms the second mechanical connection point on the upper end of the room-temperature bore of the vacuum vessel.

The mechanical connection length between the first mechanical connection point, which is located in the upper region of the vacuum vessel in a vertical cryostat, and the second connection point is minimized, in that the second mechanical connection point is likewise located in the upper region of the vacuum vessel. A small length changes less markedly during temperature fluctuations than a long length.

One class of embodiments of the NMR apparatus according to the invention has, on a portion of the path along the vacuum vessel from the first mechanical connection point to the second mechanical connection point and/or on a portion of the path along the positioning element from the second mechanical connection point to the shim system, a regulating element for regulating thermal changes in length is arranged on the relevant path, and preferably comprises a heating element and/or a cooling element and/or a heat exchanger.

With the regulating element, the temperature fluctuation on the portion can be kept small. As a result, the relative movement between the superconducting magnet and the shim system is minimized, and field homogeneity remains stable.

In certain versions of this class of embodiments, a sensor element, which preferably comprises a thermometer—in particular, a PT-100 sensor—and/or a strain measuring element, is also arranged on the relevant path, in addition to the regulating element.

As a thermal sensor element, platinum resistance thermometers (typically PT-100) are particularly suitable, because they enable accurate temperature measurements in the room temperature range.

A possibility of reducing the relative movements between the superconducting magnet and the shim system by strain monitoring is advantageous in this case. The portion of a path along the vacuum vessel, which is spoken of here, could, in common cryostats, comprise one suspension turret or all suspension turrets. The sensor element supplies the variable that must be kept constant, which is ensured by regulating the current in the heating element or in the cooling element.

In variations of these embodiments, the sensor element comprises a laser with which a change in position of an observed path portion can be detected—in particular, interferometrically—by means of an electro-optical distance measurement.

Similarly as with the thermometer and/or the strain measuring element, the laser determines a change in length, which can be regulated with the current in the heating element or in the cooling element. For example, the laser can monitor the change in length of the positioning element or of a suspension turret. It can likewise preferably be provided in these developments that at least one piezo element be present, by means of which an observed strain change of a path portion is corrected.

The piezo element can be integrated in the positioning element, for example. By applying an electrical voltage, its length can be adapted such that the overall length of the positioning element remains constant over time.

In a further class of embodiments of the NMR apparatus according to the invention, the superconducting magnet is arranged within the vacuum vessel in a helium vessel of the cryostat that is filled with liquid helium during operation, wherein the helium vessel is preferably surrounded radially by a nitrogen vessel of the cryostat filled with liquid nitrogen.

In practice, most cryostats are operated in this way. In vertical magnets, the first mechanical connection point comprises one or more weld seams, which connect the magnet suspension—in this case, the helium suspension pipes—to the vacuum vessel.

Embodiments in which the cryostat comprises a cryocooler by means of which the superconducting magnet can be cooled to its operating temperature may likewise be advantageous.

In this case, advantageously, no refilling of helium is necessary. A helium shortage therefore causes no problems.

In principle, embodiments of the NMR apparatus according to the invention in which the vacuum vessel is completely surrounded by a temperature-controlled box and preferably set up in a climate-controlled room may also be advantageous. An air-conditioned room is in principle already such a box. As examples from practice show, an additional insulation box can, however, still significantly improve the temperature control.

Further advantages of the invention will become apparent from the description and the drawings. Likewise, the features according to the invention that are mentioned above and set out in the following can each be used individually per se or together in any desired combinations. The embodiments shown and described are not to be understood as an exhaustive list, but instead are of an exemplary nature for describing the invention.

### BRIEF DESCRIPTION OF THE DRAWINGS

The invention is illustrated in the drawings and will be explained in more detail with reference to embodiments.

FIG. 1 is a schematic, vertical sectional view of an embodiment of the NMR apparatus according to the invention in which the positioning element comprises a clamping ring, wherein the contact surface of the clamping ring forms the second mechanical connection point on the upper end of the room-temperature bore of the vacuum vessel;

FIG. 2 is a schematic vertical section through an embodiment of the NMR apparatus according to the invention similar to that in FIG. 1, but with a mechanical actuator arranged in the path along the positioning element from the second mechanical connection point to the shim system;

FIG. 3 is a further embodiment of the NMR apparatus according to the invention in which the positioning element comprises a scaffold, wherein the contact surface of the scaffold forms the second mechanical connection point on the upper end of the suspension turret of the magnet suspension;

FIG. 4 is a detail of the NMR apparatus according to the invention, with the interconnection scheme for several regulating elements and sensor elements;

FIG. 5 is a detail of the NMR apparatus according to the invention, with the interconnection scheme for several regulating elements and sensor elements having only a single control circuit; and

FIG. 6 is a schematic, vertical sectional view of an embodiment of the NMR apparatus according to the invention, with a temperature-controlled fluid which keeps the suspension turrets and the positioning element at a constant temperature.

### DETAILED DESCRIPTION

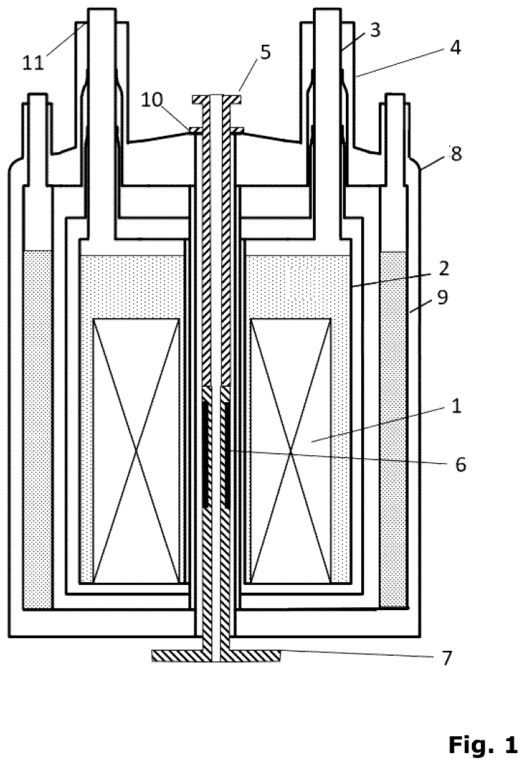

In general, the present invention relates to a modified NMR apparatus like that shown in FIGS. 1-3, with a magnet coil system for generating a homogeneous magnetic field, which comprises a superconducting magnet 1 arranged within a vacuum vessel 8 in the cold region of a cryostat. In addition, the NMR apparatus comprises a shim system 7, which contains shim elements 6 that are arranged outside the vacuum vessel 8 and can be designed as electrical coils and/or as ferromagnetic elements. The superconducting magnet 1 also has, via a magnet suspension 3, a first mechanical connection point 11 to the vacuum vessel 8, wherein the magnet suspension 3 in turn is arranged in a suspension turret 4. The shim system 7 has, via a positioning element 5, a second mechanical connection point 10; 12 to the vacuum vessel 8.

In addition to the shim elements 6, the shim system 7 typically also comprises a holding structure of the shim elements 6, so that the shim system 7 forms a unit, not just functionally, but also structurally. The holding structure makes it possible to mechanically connect the entirety of the shim elements 6 to a positioning element 5, or it serves to guide electrical lines to the shim elements 6, or, as a mechanical interface, to an NMR probehead. The conceptual distinction between positioning element 5 and other structural components, e.g., a holding structure of the shim elements 6, is given in that all structural components in a path between a second mechanical connection point 10; 12 to the vacuum vessel 8 on the one side and at least one shim element 6 on the other side are to be understood as positioning elements 5 when their strain influences the position or orientation of this shim element 6 relative to the superconducting magnet 1.

The superconducting magnet 1 is normally arranged within the vacuum vessel 8 in a helium vessel 2 of the cryostat filled with liquid helium during operation, wherein the helium vessel 2 is preferably radially surrounded by a nitrogen vessel 9 of the cryostat filled with liquid nitrogen. The cryostat may also comprise a cryocooler, by means of which the superconducting magnet 1 can be cooled to its operating temperature.

In contrast, the present invention is characterized in that, on at least one portion of a path along the vacuum vessel 8 from the first mechanical connection point 11 to the second mechanical connection point 10; 12 and/or on at least one portion of a path along the positioning element 5 from the second mechanical connection point 10; 12 to the shim system 7, only materials whose thermal expansion coefficient at operating temperature is less than 5 ppm/K are used.

It may also be favorable if, on the path along the vacuum vessel 8 from the first mechanical connection point 11 to the second mechanical connection point 10; 12 and/or on the path along the positioning element 5 from the second mechanical connection point 10; 12 to the shim system 7, materials with different thermal expansion coefficients whose thermal expansions in each case mutually compensate for one another are used in portions.

Preferably, the length of the path portion along the vacuum vessel 8 from the first mechanical connection point 11 to the second mechanical connection point 10; 12 and/or the length of the path portion along the positioning element 5 from the second mechanical connection point 10; 12 to the shim system 7 is in each case more than 50% of the overall length of the corresponding path.

FIG. 1 shows a particularly advantageous, two-part mechanical structure for the arrangement of shim elements 6 in a magnet bore. The upper part of the mechanical structure establishes the connecting path from the shim system 7 to the second mechanical connection point 10 between the clamping ring and the vacuum vessel 8, and serves by definition as a positioning element 5. The lower part of the mechanical structure is assigned to the shim system 7 and serves to hold the entirety of the shim elements 6, so as to introduce the shim elements 6 from below into the magnet bore, to receive an NMR probehead, and to guide electrical supply lines to the shim elements 6. The two-part design of the mechanical structure for the arrangement of the shim elements 6 simplifies the installation in the magnet bore. In the operating state, the two structures are mechanically connected by screws, for example. In contrast, one-piece structures, in which the shim system 7, as the entirety of all shim elements 6, has no structural components, and the positioning element 5 also serves as a holder of the shim elements 6 and can assume further of the aforementioned functions, are also conceivable.

The positioning element 5 in FIG. 1 comprises a clamping ring, the contact surface of which forms the second mechanical connection point 10 on the upper end of the room-temperature bore of the vacuum vessel 8.

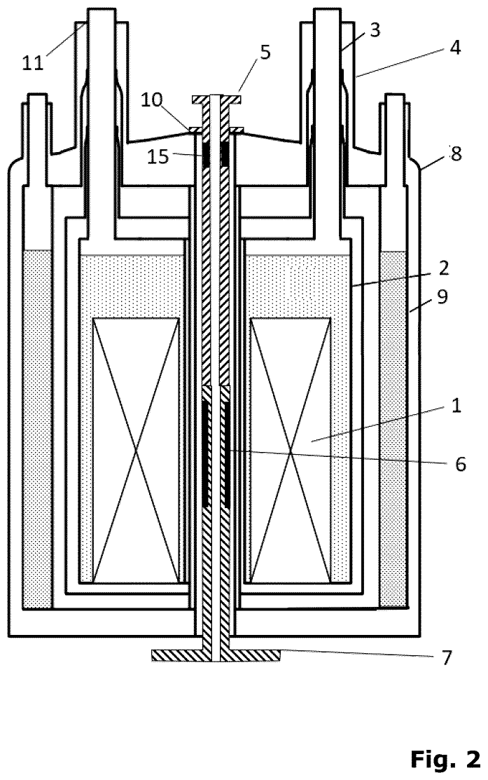

FIG. 2 shows an embodiment of the NMR apparatus like that in FIG. 1, but additionally with a mechanical actuator 15 arranged below the clamping ring 10.

As illustrated in FIG. 2, the piezo element 15 can be integrated in the positioning element 5. If the position of the shim system 7 is to be changed, the piezo element 15 can be supplied with a corresponding electrical voltage. The change in length of the piezo crystal is then proportional to the applied voltage, and negative voltages are also possible. With the thickness of a piezo stack in sandwich construction, the range of the possible shift can be adapted to the shift requirements.

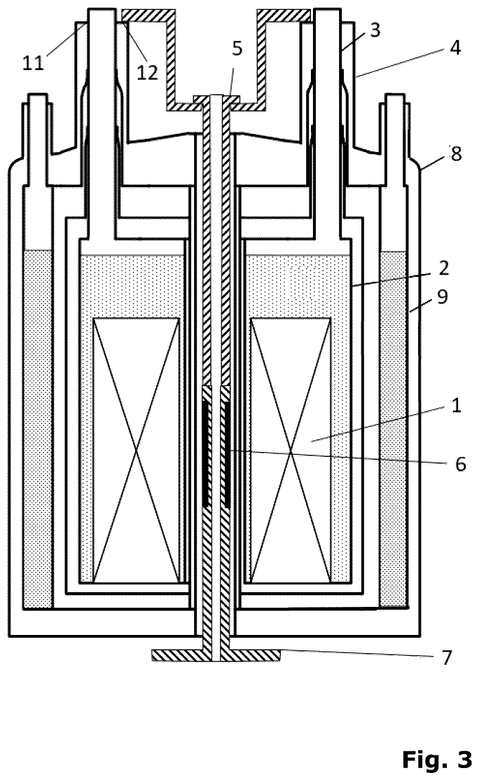

In FIG. 3 on the other hand, the positioning element for the shim system 7 is suspended via a scaffold on the suspension turrets. In this way, the first and the second mechanical connection points almost coincide, and the path along the vacuum vessel that connects the two mechanical connection points to one another is minimized. In particular, the connecting elements 12 can be produced from a material with a low thermal expansion coefficient, so that no significant strains occur during temperature fluctuations.

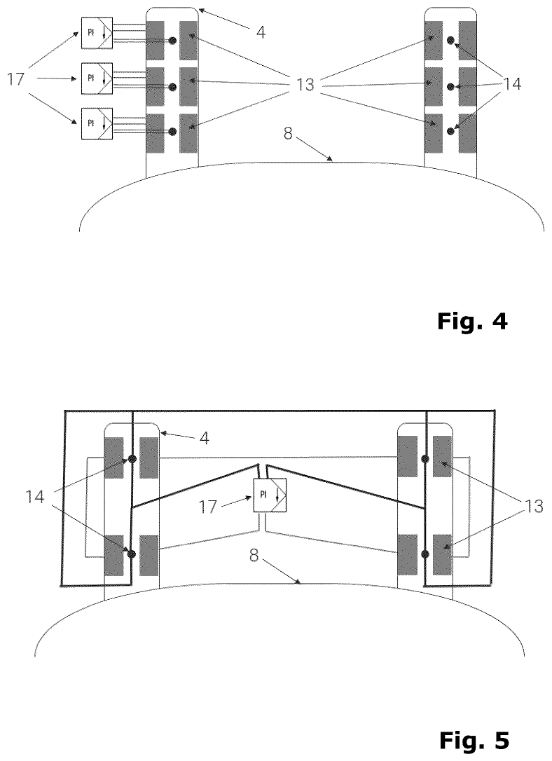

FIG. 4 presents, in a detail of a schematic vertical section through the NMR apparatus according to the invention having several regulating elements 13 and sensor elements 14, an example of controllers on the suspension turrets 4 (here: three control variables and three regulating elements per tower). This illustrates how, with several control loops, the strain changes can be kept small in portions on the different suspension turrets 4. With such a solution, maximum control of the strain is obtained. The effort required for this purpose is admittedly very large, because several current sources and several controllers are needed.

The specific exemplary embodiment of FIG. 4 shows regulating elements 13, formed as heating elements, and sensor elements 14 on the suspension turrets 4. With the aid of the sensor elements 14, the strain or the temperature of the suspension turrets 4 is measured, and the measured strain change can be counteracted with the heaters.

Shown schematically in FIG. 4 are also electronic control units 17 (here in the form of PI controllers) which regulate the current of the heating elements as a function of the measured strain. PI controllers are admittedly only one example of a wide variety of possible controllers, which are known per se from control engineering. In control engineering, there are still many other controllers, which, however, shall not be discussed in detail here. For example, PT-100 temperature sensors can be used as sensor elements 14.

For a temperature measurement, PT-100 sensors are a good choice, since they are particularly sensitive in the room temperature range. Alternatively, other temperature sensors or strain measuring elements can be used. Heating elements usually comprise a meandering wire which covers as much area as possible.

Furthermore, FIG. 4 schematically indicates the current feed of the respective sensor elements 14.

The suspension turrets 4 including the sensor elements 14 and the regulating elements 13 are usually covered with insulation material (which is, however, not shown specifically in the figure) in order to dampen fluctuations in the ambient temperature. In this example, the temperature of the suspension turrets 4 is artificially kept higher by the heaters than ambient temperature so that it is possible to react to elevations of the ambient temperature. Instead of the heating elements, cooling elements—in particular, so-called thermoelectric coolers (TEC)—may also be used. In this case, the temperature of the suspension turrets 4 is, sensibly, kept lower than ambient temperature.

While an example with a multitude of PI controllers is shown in FIG. 4, it is also possible to reduce their number by connecting several heating elements or cooling elements in series. It is also possible to use switching technology to connect the PT-100 sensors in series, in parallel, or in a combination thereof, so that only a mean temperature is used for the regulation. This often reduces the complexity and price of the required electronics, without great disadvantages.

Such an exemplary embodiment is shown in FIG. 5. However, the control over the strain of the suspension turrets 4 is somewhat less precise than in the exemplary embodiment according to FIG. 4. However, if a material with good thermal conductivity is used for the suspension turrets 4, the temperature gradient across the suspension turrets 4 can be reduced. Combined with good insulation of the suspension turrets 4 from the ambient temperature, strain regulation can be further improved.

Depending upon the application, there are a plethora of possibilities that can range between the two solutions presented here. Similar arrangements as for the suspension turrets 4 are also possible for the positioning element 5.

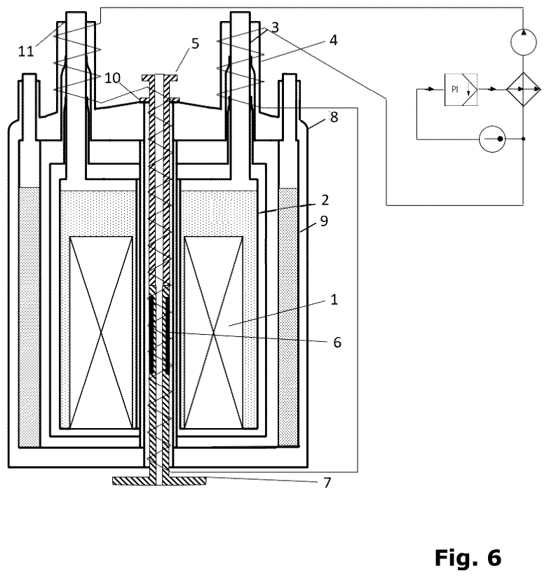

FIG. 6 shows an embodiment with a liquid circuit, which is guided along the suspension turrets 4 and the positioning element 5. An advantage of this embodiment is that only a single, regulated heating element or cooling element is necessary for the temperature stabilization of several components. A temperature-control liquid can transport large amounts of heat, so that the temperature gradients within the temperature-controlled objects can be kept small. This improves the precision of the control of thermal expansion. With insulation to the exterior space, the temperature gradient within the temperature-controlled objects can be further reduced. A gas can also be used as the temperature-control fluid. The advantage of a gas is that it can be guided openly along the positioning element 5 within the magnet bore.

### LIST OF REFERENCE SKINS

1 Superconducting magnet
2 Helium vessel
3 Magnet suspension
4 Suspension turret
5 Positioning element for the shim system
6 Shim elements
7 Shim system
8 Vacuum vessel
9 Nitrogen vessel
10 Second mechanical connection point
11 First mechanical connection point
12 Alternative second mechanical connection point
13 Regulating element
14 Sensor element
15 Mechanical actuator
17 Electronic control unit

1. An NMR apparatus having a magnet coil system for generating a homogeneous magnetic field, the apparatus comprising:
a superconducting magnet arranged within a vacuum vessel in a cold region of a cryostat,
a shim system containing shim elements arranged outside the vacuum vessel,
a magnet suspension via which the superconducting magnet has a first mechanical connection point to the vacuum vessel, and
a positioning element via which the shim system has a second mechanical connection point to the vacuum vessel,
wherein, on at least one portion of a first path along the vacuum vessel from the first mechanical connection point to the second mechanical connection point and/or on at least one portion of a second path along the positioning element from the second mechanical connection point to the shim system, only materials whose thermal expansion coefficient at operating temperature is less than 5 ppm/K are used.

2. The NMR apparatus according to claim 1, wherein a length of said at least one portion of the first path and/or a length of said at least one portion of the second path is in each case more than 50% of the overall length of the corresponding path.

3. The NMR apparatus according to claim 1, wherein materials with different thermal expansion coefficients whose thermal expansions mutually compensate for one another are used in portions on the first path and/or on the second path.

4. The NMR apparatus according to claim 1, wherein Invar is used on the at least one portion of the first path.

5. The NMR apparatus according to claim 1, wherein CFRP (carbon fiber-reinforced plastic) is used on the at least one portion of the second path.

6. The NMR apparatus according to claim 5, wherein a distance from the first mechanical connection point to the second mechanical connection point is less than 10 cm.

7. The NMR apparatus according to claim 1, wherein materials whose thermal conductivity at operating temperature is greater than 50 W/(mK) are used on at least one portion of a further path along the positioning element from the second mechanical connection point to the shim system.

8. The NMR apparatus according to claim 1, wherein the shim elements are electrical coils and/or ferromagnetic elements.

9. The NMR apparatus according to claim 1, wherein the vacuum vessel has a vertical room-temperature bore in which the shim system is arranged, and wherein the positioning element comprises a clamping ring, wherein the contact surface of the clamping ring forms the second mechanical connection point on the upper end of the room-temperature bore of the vacuum vessel.

10. The NMR apparatus according to claim 1 wherein, on a portion of the first path and/or on a portion of the second path, a regulating element for regulating thermal changes in length is arranged.

11. The NMR apparatus according to claim 10, wherein a sensor element comprising a thermometer and/or a strain measuring element, is also arranged on a portion of the first path and/or on a portion of the second path.

12. The NMR apparatus according to claim 11, wherein the sensor element comprises a laser with which a change in position of an observed path portion can be detected by means of an electro-optical distance measurement.

13. The NMR apparatus according to claim 11, further comprising at least one piezo element by which an observed change in position of a path portion can be corrected.

14. The NMR apparatus according to claim 1, wherein the superconducting magnet is arranged within the vacuum vessel in a helium vessel of the cryostat filled with liquid helium during operation.

15. The NMR apparatus according to claim 1, further comprising a cryocooler by which the superconducting magnet can be cooled to its operating temperature.
